(19) United States
(12) Patent Application Publication
(10) Pub. No.: US 2007/0152227 A1
(43) Pub. Date: Jul. 5, 2007

(54) CMOS IMAGE SENSOR

(76) Inventor: Jae Won Han, Gyeonggi-do (KR)

Correspondence Address: SHERR & NOURSE, PLLC, 620 HERNDON PARKWAY, SUITE 200, HERNDON, VA, 20170, US

(21) Appl. No.: 11/613,108

(22) Filed: Dec. 19, 2006

(30) Foreign Application Priority Data
Dec. 29, 2005 (KR) 10-2005-0134399

(51) Int. Cl. H01L 33/00

(52) U.S. Cl. 257/98

(57) ABSTRACT

Embodiments relate to a CMOS image sensor and a manufacturing a CMOS image sensor, that may be capable of enhancing a focusing function of light by forming a reflective layer between a micro lens and a photodiode, and may improve a sensitivity of an image sensor. According to embodiments, the CMOS image sensor may include a plurality of photodiodes formed on a semiconductor substrate, a first interlayer dielectric layer formed on an entire surface of the semiconductor substrate including the photodiodes, a reflective layer formed on the first interlayer dielectric layer such that the reflective layer has openings corresponding to the photodiodes, a second interlayer dielectric layer formed on an entire surface of the first interlayer dielectric layer including the reflective layer, a plurality of color filter layers formed on the second interlayer dielectric layer with a regular interval, a planarization layer formed on an entire surface of the semiconductor substrate including the color filter layers, and micro lenses formed on the planarization layer, each micro lens being placed corresponding to each photodiode.

The present application claims priority under 35 U.S.C. 119 and 35 U.S.C. 365 to Korean Patent Application No. 10-2005-0134399 (filed on Dec. 29, 2005), which is hereby incorporated by reference in its entirety.

### BACKGROUND

An image sensor may be a semiconductor device that may convert an optical image into an electric signal. An image sensor may be classified into a Charge Coupled Device (CCD) image sensor and a Complementary Metal Oxide Semiconductor (CMOS) image sensor.

A CMOS image sensor may include a photodiode that may detect light, and a CMOS logic circuit that may convert detected light into electric signals to represent the light as data. As a quantity of light received in the photodiode increases, the photo sensitivity of the image sensor may be improved.

To improve photo sensitivity, a fill factor, which is a ratio of a photodiode area to the whole area of the image sensor, may be increased. Also, to improve photo sensitivity, a photo-gathering technology may be used to change a path of light incident to an area other than the photodiode area to the photodiode area such that the light may be gathered by the photodiode.

An example of photo-gathering technology is a micro-lens. For example, a convex micro-lens may be formed on a top surface of a photodiode using a material having superior light transmittance. This may refract the incident light in such a manner that a greater amount of light may be transmitted to the photo-diode area.

For example, light parallel to an optical axis of the micro-lens may be refracted by the micro-lens and the light may be focused on a certain position of an optical axis.

A related art CMOS image sensor will be described with reference to the accompanying drawing.

Referring to FIG. 1, a CMOS image sensor may include photodiodes 11, at least one of which may be formed on semiconductor substrate 10 and may generate electric charges according to an amount of incident light. The CMOS image sensor may also include interlayer dielectric layer 12 formed on a surface of semiconductor substrate 10 including photodiodes 11. The CMOS image sensor may also include protective layer 13 formed on the interlayer dielectric layer 12. RGB color filter layers 14 may be formed on the protective layer 13 and may allow light having specific wavelength bands to pass therethrough. Planarization layer 15 may be formed on color filter layers 14, and micro lenses 16 may be provided on the planarization layer 15. Micro lenses 16 may be convex lenses having a prescribed curvature and may guide light to photodiodes 11 by way of color filter layers 14.

Instead of the photodiodes, photo gates may be used to detect light.

Physical dimensions, such as curvature, height, etc., of micro lenses 16 may be determined by taking various factors, such as a focal point of the focused light and so on, in to consideration. Polymer based resin may be used as a material for micro lenses 16 and micro lenses 16 may be formed through deposition, patterning, and reflow processes.

Micro lenses 16 may be formed with an optimal size, an optimal thickness, and an optimal radial curvature, which may be determined based on a size, a position, and a shape of a pixel, a thickness of the photo sensing element, and a height, a position and a size of a light shielding layer.

Photoresist may be used as a material for micro lenses 16. Micro lenses 16 may be formed, for example, by performing a series of processes of coating the photoresist, patterning the photoresist through an exposure and developing process to form a photoresist pattern, and reflowing the photoresist pattern.

Micro lenses 16 may allow a larger amount of light to be focused onto photodiodes 11 by passing through color filter layers 14 according to the wavelengths thereof, when natural light is incident to micro lenses 16.

The light incident to the image sensor may be focused by micro lenses 16 and may be filtered through color filter layers 14. The filtered light may then be incident to each photodiode 11 which is correspondingly located below each color filter layer 14.

A related art CMOS image sensor may have various disadvantages. For example, a sensitivity of the CMOS image sensor may be lowered, because, as shown in FIG. 2, some portions 20 of light 18 incident to photodiodes 11 may be reflected by photodiodes 11. This may degrade the focusing efficiency of the light.

### SUMMARY

Embodiments relate to an image sensor. Embodiments relate to a CMOS image sensor and a manufacturing method thereof, that may be capable of enhancing the focusing function of light by forming a reflective layer between a micro lens and a photodiode. In embodiments, a sensitivity of the image sensor may be improved.

In embodiments a CMOS image sensor may include a plurality of photodiodes formed on a semiconductor substrate while forming a regular interval therebetween, a first interlayer dielectric layer formed on an entire surface of the semiconductor substrate including the photodiodes, a reflective layer formed on the first interlayer dielectric layer such that the reflected layer has openings corresponding to the photodiodes, a second interlayer dielectric layer formed on an entire surface of the first interlayer dielectric layer including the reflective layer, a plurality of color filter layers formed on the second interlayer dielectric layer while forming a regular interval therebetween, a planarization layer formed on an entire surface of the semiconductor substrate including the color filter layers, and micro lenses formed on the planarization layer corresponding to the photodiodes.

In embodiments, a method of manufacturing a CMOS image sensor may include forming a first interlayer dielectric layer on a semiconductor substrate where a plurality of photodiodes are formed, forming a reflective layer on the first interlayer dielectric layer such that the reflective layer has openings respectively corresponding to the photodiodes, forming a second interlayer dielectric layer on an entire surface of the first interlayer dielectric layer including the reflective layer, forming a plurality of color filter layers on the second interlayer dielectric layer with a regular interval, forming a planarization layer on an entire surface of the semiconductor substrate including the color filter layers, and forming micro lenses on the planarization layer such that the micro lenses are placed corresponding to the photodiodes.

In embodiments, a CMOS image sensor may include a micro lens, a photodiode for absorbing light incident through the micro lens, and a reflective layer that may re-reflect some of the light, which is reflected from the photodiode, toward the photodiode.

The reflective layer may be formed on a top of a region on which the photodiode is formed, and openings for passing lights incident through the micro lenses may be formed at a center part of the reflective layer.

### BRIEF DESCRIPTION OF DRAWINGS

FIG. 1 is an example cross-sectional diagram illustrating a structure of a related art CMOS image sensor;

FIG. 2 is an example cross-sectional diagram illustrating a structure of a related art CMOS image sensor where reflection occurs by photodiodes;

FIG. 3 is an example cross-sectional diagram illustrating a structure of a CMOS image sensor according to embodiments;

FIG. 4 is an example cross-sectional diagram illustrating a structure of a CMOS image sensor according to embodiments where re-reflection may occur by a reflective layer; and

FIGS. 5A to 5G are example cross-sectional diagrams illustrating a procedure for manufacturing a CMOS image sensor according to embodiments.

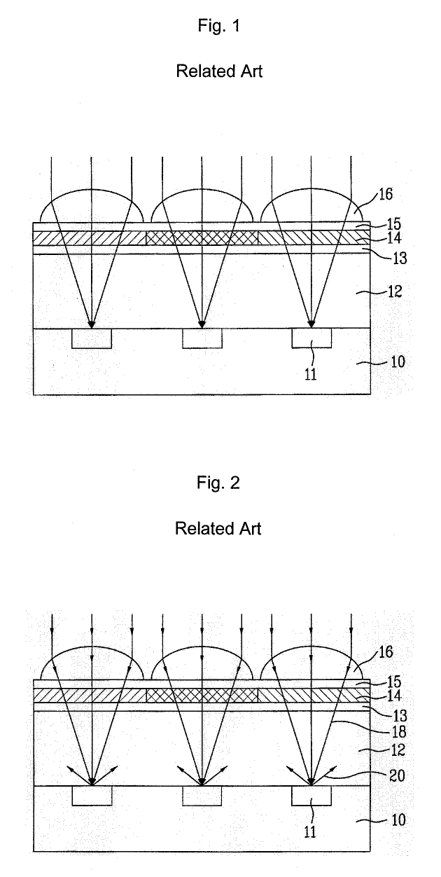

### DETAILED DESCRIPTION OF EMBODIMENTS

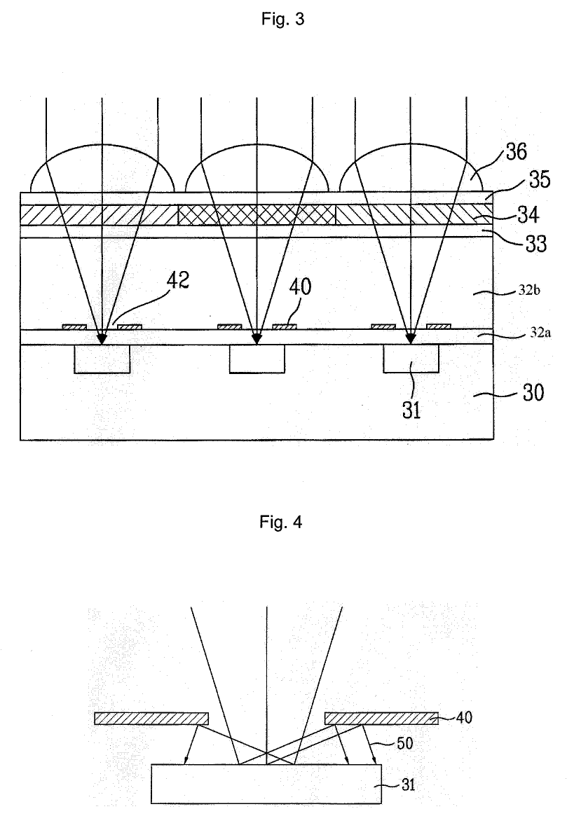

Referring to FIG. 3, a CMOS image sensor according to embodiments may include photodiodes 31, at least one of which may be formed on semiconductor substrate 30. Photodiodes 31 may generate electric charges according to an amount of incident light received. First interlayer dielectric layer 32A may be formed on a surface of semiconductor substrate 30 including photodiodes 31. Reflective layer 40 may be formed on first interlayer dielectric layer 32A. Reflective layer 40 may have openings 42, each of which may be formed on each of photodiodes 31, according to embodiments. Second interlayer dielectric layer 32B may be formed over a surface of first interlayer dielectric layer 32A including reflective layer 40. Protective layer 33 may be formed on a surface of second interlayer dielectric layer 32B. Color filter layers 34 may be formed on protective layer 33 corresponding to photodiodes 31 and may allow light having specific wavelength bands to be irradiated on photodiodes 31. Planarization layer 35 may be formed on a surface of the semiconductor substrate including color filter layers 34, and micro lenses 36 may be formed on planarization layer 35 corresponding to photodiodes 31 and may focus light onto photodiodes 31.

Reflective layer 40 may include a metallic layer which may be any one of metallic layers used in a manufacturing process of a semiconductor device. Reflective layer 40 may be formed on first transparent interlayer dielectric layer 32A through any one of metallic layer deposition methods used to form a metallic layer during a manufacturing process of a semiconductor device. In embodiments, a CVD method or a PVD method may be used to form reflective layer 40.

In embodiments, reflective layer 40 may be formed to have openings 42 by patterning and etching a thin layer deposited by a deposition process. The openings may be patterned such that light focused by micro lenses 36 may be incident to photodiodes 31. In embodiments, micro lenses 36 may be formed with a convex hemispheric shape and may facilitate focusing of light.

FIG. 4 is a diagram illustrating a function of reflective layer 40, according to embodiments.

Referring to FIG. 4, reflective layer 40 may be formed on first interlayer dielectric layer 32A. Reflective layer 40 may re-reflect light 50, which may be reflected upward by photodiode 31, back toward photodiode 31. According to embodiments, a sensitivity of a CMOS image sensor may be improved since the focusing efficiency of the light may be enhanced.

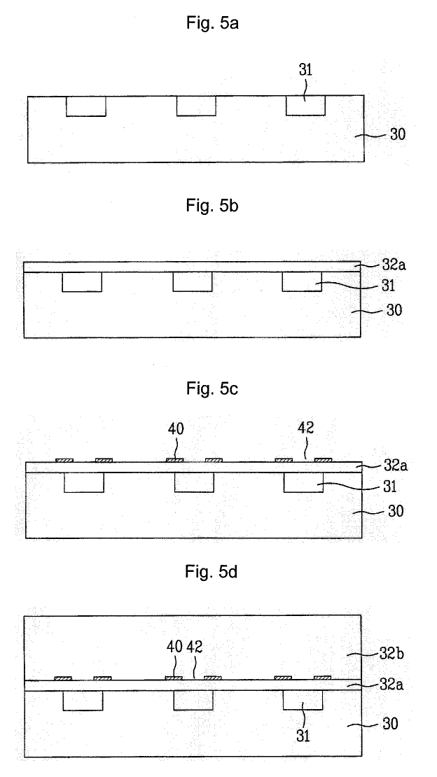

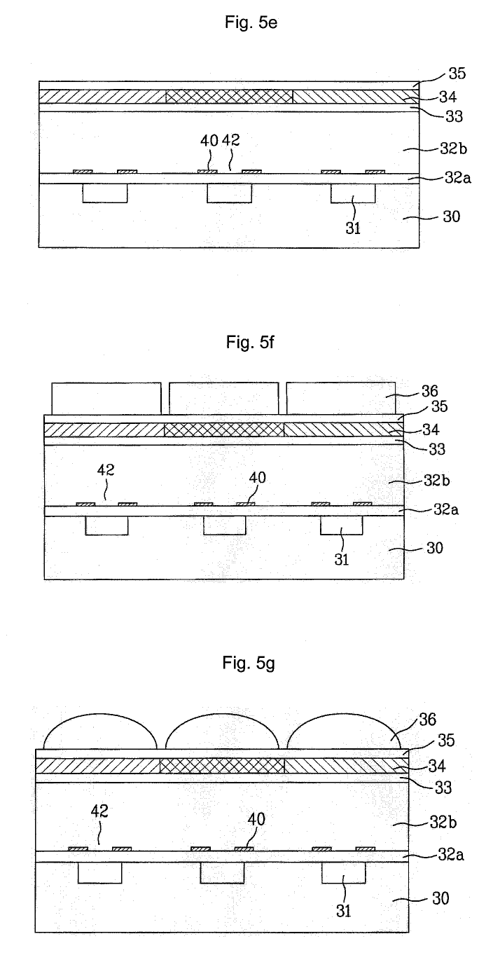

FIGS. 5A to 5G are example cross-sectional diagrams illustrating a procedure for manufacturing a CMOS image sensor according to embodiments.

Referring to FIG. 5A, a plurality of photodiodes 31 may be provided on semiconductor substrate 30, for example in the form of a matrix.

A process of forming photodiodes on semiconductor substrate 30 is known in the art, and thus a description thereof will be omitted.

Referring to FIG. 5B, first interlayer dielectric layer 32A may be formed on a surface of semiconductor substrate 30, for example where photodiodes 31 are formed.

Metallic layer 40 may be deposited on a surface of first interlayer dielectric layer 32A and may be patterned, as illustrated in FIG. 5C.

Referring to FIG. 5C, patterned metallic layer 40 may have a shape that surrounds (or blocks) edge regions of photodiodes 31. Openings 42 for guiding light incident through micro lenses may be formed in center parts of patterned metallic layer 40.

Metallic layer 40 may be patterned in a shape illustrated in FIG. 5C, and may function as a reflective layer for re-reflecting light, which may be reflected from photodiodes 31, back toward photodiodes 31.

According to embodiments, metallic layer 40 may include a material substantially identical to a material used to form various metallic patterns during a manufacturing process of a semiconductor device.

Referring to FIG. 5D, second interlayer dielectric layer 32B may be formed on a surface of first interlayer dielectric layer 32A, for example where reflective layer 40 may be formed. In embodiments, second interlayer dielectric layer 32B may include a material substantially identical to a material used to form first interlayer dielectric layer 32A.

Referring to FIG. 5E, planar protective layer 33 may be formed on second interlayer dielectric layer 32B. Planar protective layer 33 may protect a device from moisture and scratches.

A dyeable resist may be coated on protective layer 33. A patterning process may then be carried out and may form RGB color filter layers 34, which may filter light having specific wavelength bands.

Planarization layer 35 may be formed on color filter layers 34. Those skilled in the art will readily understand that a thickness of planarization layer 35 may be adjusted to control a focal length of micro lenses 36, which may be formed through subsequent processes.

Referring to FIG. 5F, a material layer used to form micro lenses 36, such as resist, SiON or the like, may be deposited on planarization layer 35.

The material layer for micro lenses 36 may be selectively patterned, for example by an exposure and development process, and may thereby form micro lens patterns 36 corresponding to photodiodes 31.

Referring to FIG. 5G, a reflow process may be carried out with respect to the micro lens patterns 36. The reflow process may occur at a temperature of approximately 120° C. to 200° C., and may thereby form micro lenses 36, for example having a hemispheric shape. Thereafter, micro lenses 36 may be cured, for example by applying ultraviolet rays thereto.

According to embodiments, when a CMOS image sensor is fabricated, for example through the above-mentioned manufacturing process, light incident through micro lenses 36 may pass through openings 42 of reflective layer 40 and may then be guided into photodiodes 31.

Some of the light introduced into photodiodes 31 may be reflected from surfaces of photodiodes 31. However, a probability of re-reflection toward photodiodes 31 may increase due to reflective layer 40. Therefore, in embodiments, the photo focusing rate of photodiodes 31 may rise.

Hence, according to embodiments, a focusing efficiency of light may be enhanced since the light reflected from the photodiodes may be reabsorbed into the photodiodes. As a result, the sensitivity of the CMOS image sensor according to embodiments may be improved.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a photodiode formed over a semiconductor substrate;
a reflective layer formed over the photodiode and configured to have an opening corresponding to a location of the photodiode; and
a micro lens formed over the reflective layer, the micro lenses configured to provide light to the photodiode.

2. The device of claim 1, wherein the reflective layer is configured to re-reflect light to the photodiode that has reflected off of the photodiode.

3. The device of claim 1, further comprising a plurality of photodiodes formed over the semiconductor substrate; and
a plurality of micro lenses formed over the reflective layer, each aligned with one of the plurality of photodiodes, respectively,
wherein the reflective layer is configured to have a plurality of openings corresponding to locations of the plurality of photodiodes.

4. The device of claim 3, further comprising:
a first interlayer dielectric layer formed over the surface of the semiconductor substrate including the photodiodes;
a second interlayer dielectric layer formed over a surface of the first interlayer dielectric layer including the reflective layer;
a plurality of color filter layers formed over the second interlayer dielectric layer having a regular interval therebetween; and
a planarization layer formed on the surface of the semiconductor substrate including the color filter layers,
wherein the reflective layer is formed over the first interlayer dielectric layer and wherein the micro lenses are formed on the planarization layer.

5. The device of claim 4, wherein the first interlayer dielectric layer comprises a material substantially identical to a material comprising the second interlayer dielectric layer.

6. The device of claim 1, wherein the reflective layer comprises a metallic material.

7. The device of claim 1, wherein the opening corresponds to a region where light focused by the micro lens is incident to the photodiode.

8. The device of claim 1, wherein the reflective layer has a shape that substantially covers an edge region of the photodiode.

9. The device of claim 1, wherein the micro lens is substantially aligned with a location of the photodiode.

10. A method comprising:
forming a plurality of photodiodes over a semiconductor substrate;
forming a reflective layer over the plurality of photodiodes, the reflective layer having openings corresponding to locations of the photodiodes, respectively; and
forming a plurality of micro lenses over the reflective layer, such that each of the micro lenses is substantially aligned with each of the photodiodes, respectively.

11. The method of claim 10, further comprising:
forming a first interlayer dielectric layer over the semiconductor substrate and the plurality of photodiodes;
forming the reflective layer over the first interlayer dielectric layer such that the reflective layer has openings corresponding to locations of the photodiodes, respectively;
forming a second interlayer dielectric layer over the first interlayer dielectric layer and the reflective layer;
forming a plurality of color filter layers over the second interlayer dielectric layer having a regular interval between each of the plurality of color filters;
forming a planarization layer over the plurality of color filter layers; and
forming the plurality of micro lenses over the planarization layer, such that the micro lenses are configured to provide light to respective photodiodes.

12. The method of claim 11, wherein the first interlayer dielectric layer comprises a material substantially identical to a material forming the second interlayer dielectric layer.

13. The method of claim 10, wherein the reflective layer comprises a metallic material.

14. The method of claim 10, wherein the openings correspond to regions where light focused by the micro lenses is incident to the photodiodes.

15. The method of claim 10, wherein the reflective layer has a shape that substantially covers edge regions of the photodiodes.

16. The method of claim 10, wherein the reflective layer is configured to re-reflect light that has reflected off of the photodiodes back to the corresponding photodiodes.

17. A device comprising:
a micro lens;
a photodiode configured to absorb light provided through the micro lens; and
a reflective layer configured to re-reflect at least a portion of the light that is reflected from the photodiodes, back toward the photodiodes.

18. The device of claim 17, wherein the reflective layer is formed above a region where the photodiode is formed.

19. The device of claim 17, wherein the reflective layer is formed substantially over the photodiode and includes an opening configured to allow the light provided through the micro lens to pass through the opening to the photodiode.

20. The device of claim 19, wherein the reflective layer on either side of the opening substantially covers edge regions of the photodiodes.
